(19) United States
(12) Patent Application Publication
(10) Pub. No.: US 2010/0327979 A1
(43) Pub. Date: Dec. 30, 2010

(54) Current Detection Apparatus and Control System Using the Same

(75) Inventors: Nobuyasu KANEKAWA, Hitachi (JP); Teppei Hirotsu, Hitachi (JP); Takayuki Hashimoto, Tokai (JP); Itaru Tanabe, Naka (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi Automotive Systems, Ltd., Hitachinaka-shi (JP)

(21) Appl. No.: 12/826,429

(22) Filed: Jun. 29, 2010

(30) Foreign Application Priority Data
Jun. 30, 2009 (JP) 2009-154530

(51) Int. Cl. H03F 3/04

(52) U.S. Cl. 330/297

(57) ABSTRACT

A highly accurate current detection apparatus is realized in a one-chip LSI. An end of a current detector is connected to an analog power supply (VACC) or a virtual analog ground potential (VAG) of a voltage amplifier and an A/D converter, and a predetermined voltage is supplied between the voltage amplifier and the virtual ground potential (VAG) by a power supply.

### BACKGROUND OF THE INVENTION

This invention relates to a current detection apparatus and a control system using the apparatus, or in particular, to a current detection apparatus capable of detecting a current with high accuracy and a control system using the apparatus.

With the spread of electronic control of various objects, motorized actuators such as a motor and a solenoid have come to be widely used for converting an electric signal into a mechanical motion or a hydraulic pressure. In order to control these motorized actuators with high accuracy, the current detection with high accuracy is essential. Also, in order to prevent a burning or the like at the time of a fault, the protection is required by detecting an overcurrent.

The recent progress of the semiconductor technology, on the other hand, has realized a one-chip LSI by integrating the circuits required for the electronic control.

In order to detect an overcurrent with a circuit configuration with common ground, a current detection function is required to be provided on the high side near a power supply. Since the CMRR (common-mode rejection ratio) of an amplifier is limited, however, the current detection error caused by the variation in the source voltage poses a problem. It is very difficult to amplify and detect a potential difference of the order of several mV to several tens of mV across a shunt resistor in an environment subjected to the common-mode voltage variation of several volts. Although an operational amplifier is designed with a very high CMRR, the CMRR of the amplifier is deteriorated considerably depending on the accuracy of the resistors used in peripheral circuits. Also, due to the large voltage variation at the output terminal, the detection of the current (phase current) flowing in the motorized actuator requires a special technique to secure a higher accuracy than the current detection on the high side.

Various methods are available to prevent the current detection error due to the voltage variation. They include a method in which a current is measured by flowing a reference current to a reference resistor so that the voltage drop across the reference resistor becomes equal to a voltage drop across the shunt resistor developed by the current to be measured, as disclosed in “LT6100 Precision, Gain Selectable High Side Current Sense Amplifier, LT 0506 REV B, LINEAR TECHNOLOGY CORPORATION 2005”, a method in which a current is retrieved while being isolated using a current transformer as disclosed in JP-A-2004-228268 and JP-A-2007-27216, and a method in which the potential difference generated across a resistor (shunt resistor) in proportion to the current is retrieved after being amplified by an isolated amplifier as disclosed in JP-A-3-108907 and JP-A-4-189006 or after being amplified by an amplifier with the ground potential maintained constant with respect to a source voltage as disclosed in JP-A-10-75598.

Also, a current detection method has been disclosed by JP-A-2006-203415 in which the loss, i.e. heating in the shunt resistor is reduced by detecting a division current of a current with a sense MOS.

### SUMMARY OF THE INVENTION

The methods described above are superior as far as the current detection with high accuracy is concerned. To enjoy the recent progress of the semiconductor technology and realize a one-chip LSI by integrating these circuits for electronic control, however, a further consideration is desired. In the method disclosed in “LT6100 Precision, Gain Selectable High Side Current Sense Amplifier, LT 0506 REV B, LINEAR TECHNOLOGY CORPORATION 2005”, a rail-to-rail amplifier capable of differential operation with a source voltage or an input voltage or an amplifier capable of differential operation with an input voltage higher than the source voltage is required. Therefore, the configuration of the amplifier is complicated, often resulting an increased area required for the circuits. Realization of the current transformer with a one-chip LSI as disclosed by JP-A-2007-27216 and JP-A-2004-228268, on the other hand, is low in practicability. Also, the transformer contained in the isolated amplifier in JP-A-4-189006 and JP-A-3-108907 makes the realization of a one-chip LSI impracticable. Further, the method disclosed by JP-A-10-75598 in which the ground potential is maintained at a constant value, though realizable with individual parts, fails to take the realization with a one-chip LSI into consideration. Furthermore, in the case where the phase output current is measured, the considerable change in the operation potential caused by the switching operation of the semiconductor device cannot be easily handled.

Accordingly, it is an object of this invention to realize a high-accuracy current detection apparatus with a one-chip LSI.

In order to achieve this object, according to this invention, there is provided a current detection apparatus configured as described below.

(1) One end of a current detector is connected to an analog power supply or an analog virtual ground potential of a voltage amplifier and an analog/digital converter, and a power supply for supplying a predetermined voltage between the power supply and the virtual ground potential of the voltage amplifier is inserted.

(2) The output voltage of the current detector is amplified by the voltage amplifier, and the amplified signal is converted into a digital signal by the A/D converter.

(3) A part of a single semiconductor substrate is isolated from the remaining part thereof with an oxide film, and the voltage amplifier and the A/D converter are formed in the part of the substrate isolated from the other part.

(4) More desirably, a back substrate of the substrate isolated from the remaining part with the oxide film is connected to one end of the current detector.

As described above, according to this invention, an accurate current detection becomes possible, resulting in the accurate current control operation on the one hand, and the motorized actuator can be controlled more smoothly on the other hand, thereby making possible a highly accurate, comfortable electronic control. Also, the integration of the essential parts of the control system on the same SOI substrate 100 can reduce the size of the control system.

Other objects, features and advantages of the invention will become apparent from the following description of the embodiments of the invention taken in conjunction with the accompanying drawings.

### BRIEF DESCRIPTION OF THE DRAWINGS

FIG. 1 shows a basic embodiment of this invention.

FIG. 2 shows the operation of the embodiment of FIG. 1.

FIG. 3 shows a method of packaging on a chip according to an embodiment.

FIG. 4 is a diagram for explaining the stray capacitance with the ground.

FIG. 5 shows an embodiment in which an analog power supply VACC is connected to the potential at an end of a current detector 3.

FIG. 6 shows the operation of the embodiment in FIG. 5.

FIG. 7 shows an embodiment in which a high-side driver 1 includes the current detector 3.

FIG. 8 shows an embodiment using a sense MOS.

FIG. 9 shows an embodiment which compensates for the voltage drop across a shunt resistor 31.

FIG. 10 shows a power supply 11 (regulator) according to an embodiment.

FIG. 11 shows an amplifier 12 according to an embodiment.

FIG. 12 shows an embodiment in which the output of the amplifier 12 is shifted in level.

FIG. 13 shows a level shift unit 4 according to an embodiment.

FIG. 14 shows an embodiment in which the current detector 3 is inserted in a phase current path.

FIG. 15 shows the operation according to the embodiment of FIG. 14.

FIG. 16 shows an embodiment in which the current detector 3 is inserted in the phase current path.

FIG. 17 shows the operation according to the embodiment of FIG. 16.

FIG. 18 shows an isolator 40 according to an embodiment (differential).

FIG. 19 shows an isolator 40 according to an embodiment (differential).

FIG. 20 shows an isolator 40 according to an embodiment (single end).

FIG. 21 shows the power supply 11 (charge pump) according to an embodiment.

FIG. 22 shows a control system according to an embodiment.

FIG. 23 shows an automatic transmission control system according to an embodiment.

FIG. 24 shows a DC brushless motor control system according to an embodiment.

### DETAILED DESCRIPTION OF THE EMBODIMENTS

Embodiments of the invention are explained below with reference to the accompanying drawings.

### First Embodiment

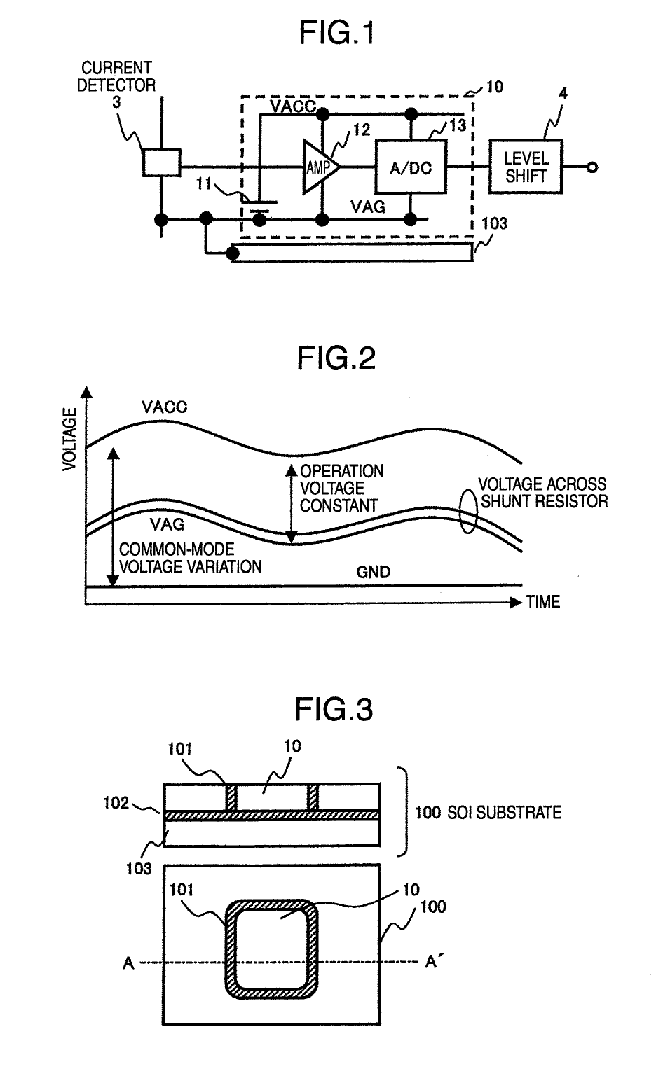

FIG. 1 shows a basic embodiment of this invention, in which the virtual analog ground (VAG) potential of an amplifier 12 for detecting a current and an A/D converter 13 is connected to the potential at one end of a current detector 3. Further, in order to activate the amplifier 12 and the A/D converter 13, a power supply 11 for supplying a predetermined voltage is arranged between the analog power supply VACC and the analog virtual ground potential VAG. According to this embodiment, as shown in FIG. 2, no common-mode component is contained in the voltage across the shunt resistor in the current detector 3, and therefore, the occurrence of an error in the current detection value which otherwise might be caused by the common-mode component is prevented.

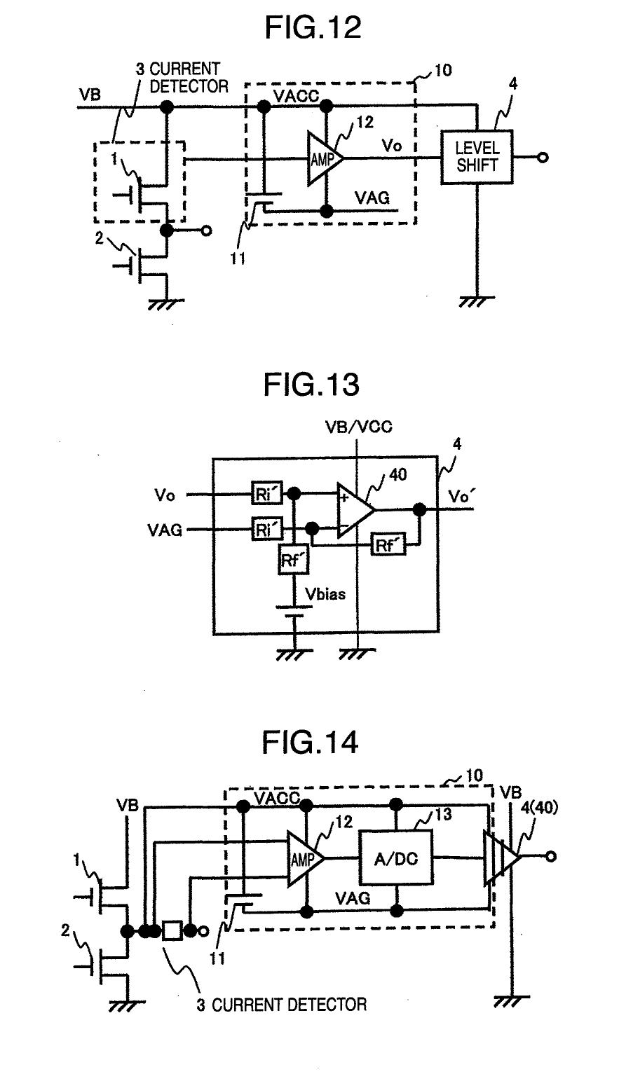

Finally, the signal based on the VAG potential is converted to a signal level based on the GND potential by a level shift unit 4. According to this embodiment, the analog signal is changed in signal level by the level shift unit 4 after being converted to a digital signal in order to avoid the effect of the voltage error which otherwise might be caused by the level shift. Even an analog signal can be directly changed in level, however, if amplified by the amplifier 12 to a sufficient amplitude to allow for the voltage error due to the level shift. An embodiment in which an analog signal is changed in level directly is shown in FIGS. 12 and 13.

FIG. 3 shows a method of packaging on a chip according to an embodiment. A region 10 defined by an insulating layer 101 is formed on a SOI (Silicon on Insulator) substrate having an insulating layer 102 at the central portion of the semiconductor substrate, and the amplifier 12 and the A/D converter 13 are formed in the region 10.

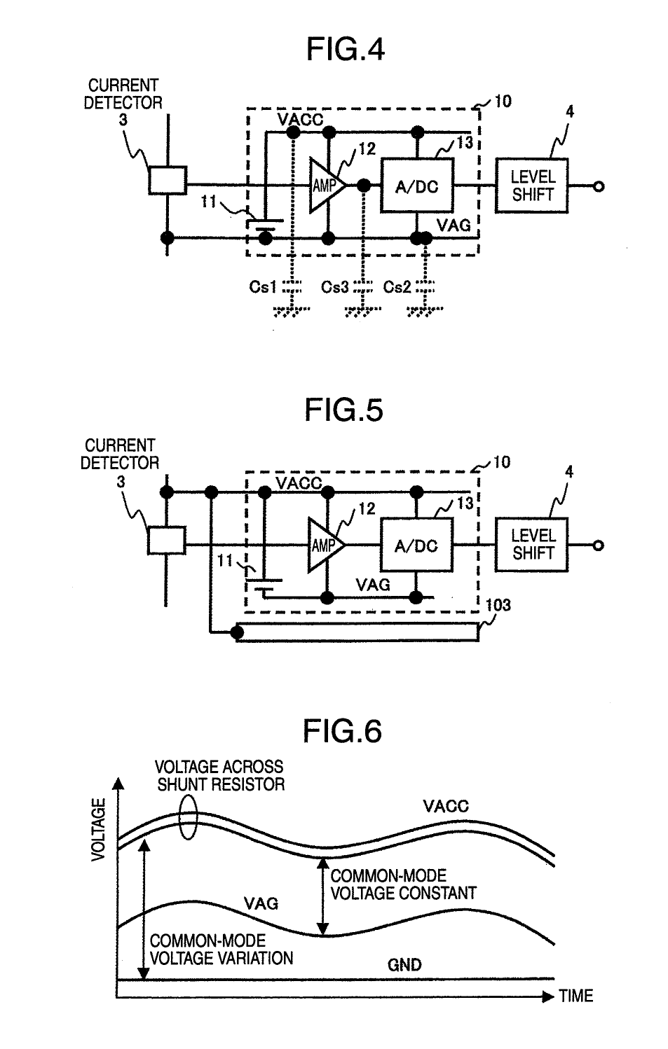

Further, the semiconductor substrate 103 on the back of the region 10 is desirably connected to the virtual analog ground (VAG) potential in the embodiment shown in FIG. 1. In the case where the semiconductor substrate 103 is not connected to the virtual analog ground (VAG) potential, as shown in FIG. 4, the potential at each part of the amplifier 12 and the A/D converter 13 would fail to follow the potential at the one end of the current detector 3 due to stray capacitances Cs1, Cs2, Cs3 between the analog power supply VACC, the analog virtual ground VAG or other wirings and the ground, with the result that a common-mode voltage would be generated and a current detection error would be caused by the common-mode component. In view of this, as shown in FIG. 1, the semiconductor substrate 103 on the back of the region 10 is connected to the virtual analog ground VAG as shown in the embodiment of FIG. 1. In this way, the electrostatic coupling due to the stray capacitances Cs1, Cs2, Cs3 is rejected to prevent the error of the current detection value which otherwise might be caused by the common-mode component.

### Second Embodiment

FIG. 5 shows a basic embodiment of the invention, in which an analog power supply VACC of an amplifier 12 for detecting a current and an A/D converter 13 is connected to the potential at an end of a current detector 3. According to this embodiment, as shown in FIG. 6, no common-mode component is contained in the voltage across a shunt resistance in the current detector 3, and therefore, the occurrence of an error of the current voltage value which otherwise might be caused by the common-mode component is prevented.

Further, a semiconductor substrate 103 on the back of a region 10 is desirably connected to the analog power supply VACC according to the embodiment shown in FIG. 5.

Which of the embodiments shown in FIGS. 1 and 5 is to be selected depends on which embodiment can realize the power supply 11 more easily.

In the case where both the analog power supply VACC and the virtual ground potential VAG assume values between the source voltage supplied from an external source such as a battery voltage VB and the ground potential GND, the power supply 11 can generate the analog power supply VACC and the virtual analog ground potential VAG by dividing the battery voltage VB and the ground potential GND. In the case where the embodiment shown in FIG. 1 or 5 meets this condition, the power supply 11 can be easily realized, and therefore, such an embodiment should be employed. In that case, the power supply 11 can be realized by a regulator to divide the voltage between itself and the amplifier 12 and the A/D converter 13 providing loads.

In the case where neither the embodiment shown in FIG. 1 nor the embodiment shown in FIG. 5 meets the condition, on the other hand, the power supply 11, though somewhat complicated, can be realized by use of a boosting (step-up) power supply or a negative voltage source using a charge pump.

### Third Embodiment

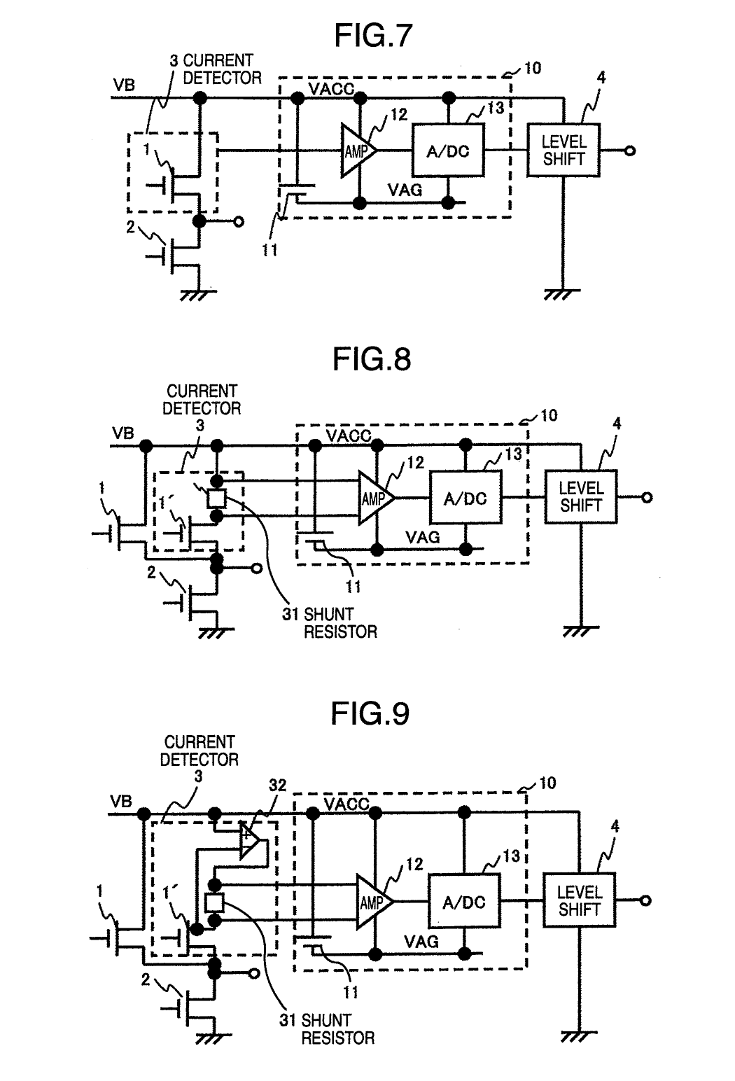

An embodiment in which the current detector 3 is included in the high-side semiconductor element 1 is shown in FIG. 7. According to the embodiment shown in FIG. 1, the relation VACC>VB holds, and therefore, a charge pump is required as the power supply 11 to generate VACC. According to the embodiment shown in FIG. 5, on the other hand, the relation can hold that VB>VACC>VAG>GND, and therefore, a regulator can be used as the power supply 11.

Incidentally, this embodiment is intended to reduce the loss by directing the free-wheel current which is flowing in an inductive load into a semiconductor element 2 instead of to a diode when the semiconductor element 1 is turned off. In this way, not only the efficiency is improved but also a compact device is realized by reducing the heating. In this case, a negative voltage is impressed on the semiconductor element 2, and therefore, the isolation of the semiconductor element 2 by means of SOI is essential to prevent the latch-up condition. Specifically, the method according to this invention in which the region 10 is isolated with SOI is understood to have a high affinity with the method in which the loss is reduced by isolating the semiconductor element 2 with SOI and supplying the free-wheel current thereto.

### Fourth Embodiment

The current detector 3 is typically so configured that a shunt resistor is inserted in the current path and the voltage across the shunt resistor is measured. On the other hand, FIG. 8 shows an embodiment in which a small semiconductor element 1′ is connected in parallel to a large semiconductor element 1, and a voltage is measured which appears across a shunt resistor 31 inserted in the current path of the small semiconductor element 1′. In this case, the currents flowing in the semiconductor element 1 and the small semiconductor element 1′ are proportional to the inverse ratio of the on-resistances, i.e. area ratio therebetween. By decreasing the area of the semiconductor element 1′ sufficiently as compared with the area of the semiconductor element 1, therefore, the current flowing in the shunt resistor 31 can also be decreased, thereby making it possible to reduce the loss due to the voltage drop across the shunt resistor 31. This configuration with a current supplied in a smaller amount can reduce the cost and capacity of the shunt resistor 31 which is otherwise required to use a high-accuracy resistor so as to secure a high measurement accuracy. Further, by suppressing the temperature increase due to the heating, the measurement error caused by the temperature coefficient of resistance can also be reduced.

### Fifth Embodiment

FIG. 9 shows still another embodiment in which the current measurement error due to the voltage drop across the shunt resistor 31 is prevented. In the embodiment of FIG. 8, the terminal voltage of the semiconductor element 1 on VB side is VB, whereas the terminal voltage of the semiconductor element 1′ on VB side is lower than VB by the voltage drop across the shunt resistor 31. In other words, the ratio of the currents between the semiconductor element 1 and the semiconductor element 1′ is not the inverse ratio of the on-resistances thereof, but the current flowing in the semiconductor element 1′ is smaller by the voltage drop across the shunt resistor 31. In the configuration of FIG. 9, therefore, an operational amplifier 32 is used to hold the VB-side terminal potential of the semiconductor element 1′ at the same level as VB. Thus, the current ratio between the semiconductor elements 1 and 1′ can be the inverse ratio of the on-resistances thereof. Incidentally, the operational amplifier 32, which is required to output a voltage higher than VB, requires a higher power supply than VB. In the case where a N-channel MOS-FET capable of reducing the area is used as the semiconductor element 1, however, a boosting (step-up) power supply higher than VB is essential for driving, and this requirement is met by the particular power supply.

### Sixth Embodiment

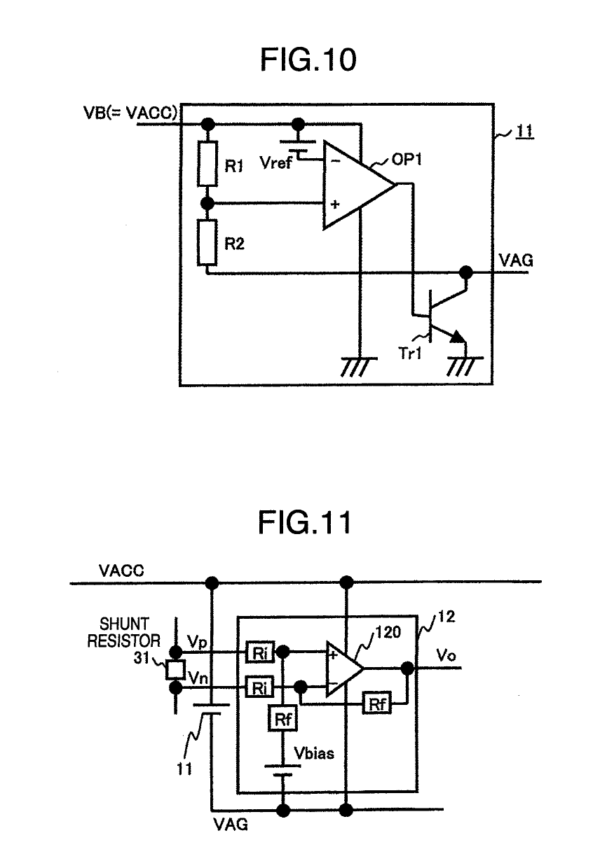

FIG. 10 shows a regulator constituting the power supply 11 according to an embodiment. The potential difference between VB and VAG is divided by resistors R1 and R2, and the transistor Tr1 is controlled in such a manner that the voltage obtained by dividing and the reference voltage Vref are equal to each other as the result of comparison in the operational amplifier OP1. Thus, the relation holds that

VB−VAG=Vref·(R1+R2)/R1

### Seventh Embodiment

FIG. 11 shows a typical differential amplifier constituting the amplifier 12 according to an embodiment. The output voltage V0 is given by the equation below.

Vo=(Vp−Vn)·Rf/Ri+Vbias

where Vbias is for regulating the voltage Vo within the operation voltage range of the operational amplifier 120, i.e. between VACC and VAG.

### Eighth Embodiment

FIG. 12 shows an embodiment in which the output of the amplifier 12 is shifted in level by the level shift unit 4. The level shift unit 4 can be realized by a typical differential amplifier, as shown in FIG. 13. Incidentally, the operational amplifier 40 operates on GND and VB or desirably VCC. In this case as well, like in FIG. 11, the output voltage Vo′ is expressed by the equation described below.

Vo′=(Vo−VAG)·Rf′/Ri′+Vbias′

where Vbias′ is for regulating the voltage Vo′ in the operation voltage range of the operational amplifier 40, i.e. between VB or VCC and GND.

### Ninth Embodiment

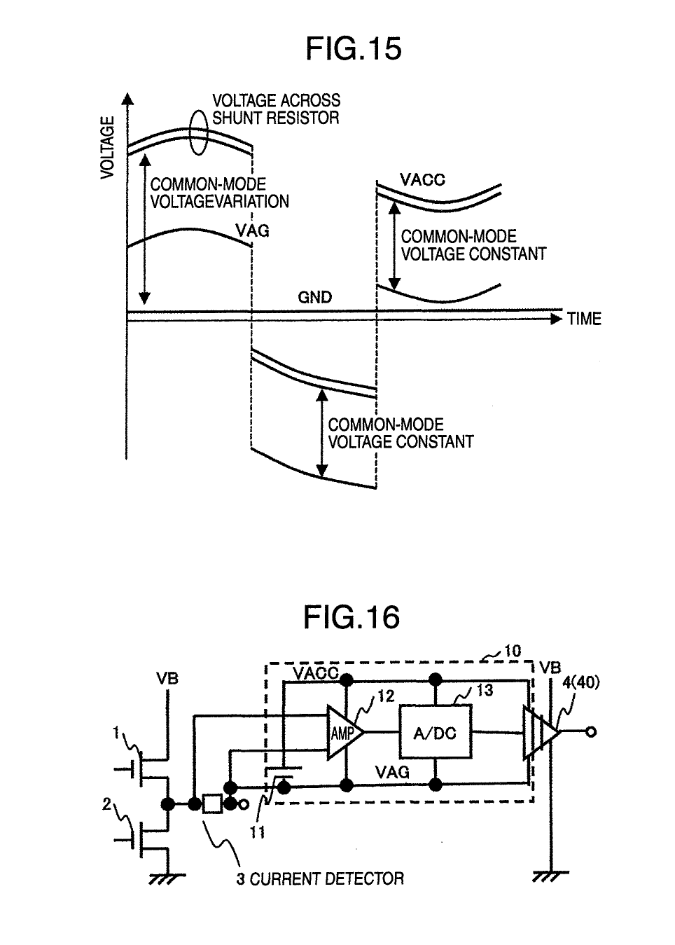

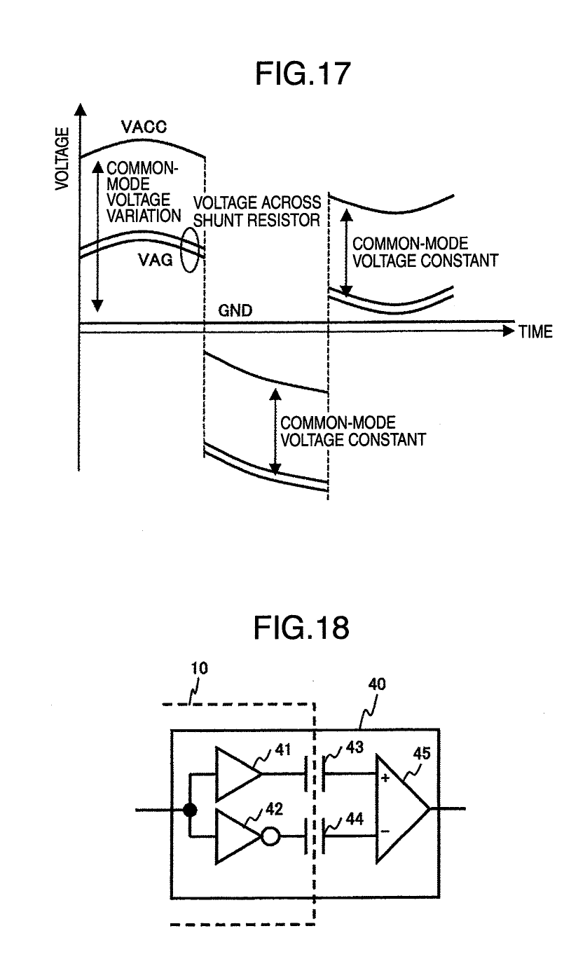

FIG. 14 shows an embodiment in which the current detector 3 is inserted in the phase current path and the potential upstream of the current detector 3 is set to VACC. Also, FIG. 16 shows an embodiment in which the current detector 3 is inserted in the phase current path and the potential downstream of the current detector 3 is set to VAG. In this case, the potential of the current detector 3 is VB when it is high and, when the free-wheeling current flows through the semiconductor element 2, the potential is reduced below GND and the potential at each point is varied as shown in FIGS. 15 and 17.

As a result, neither VACC nor VAG is settled between VB and GND. Therefore, both cases require a boosting power supply or a negative power supply using a charge pump as the power supply 11. Also, an isolator 40 may be used as the level shift unit 4 which can transmit the signal in isolation. As another alternative, the level shift unit 4 shown in FIG. 13 may be used.

### Tenth Embodiment

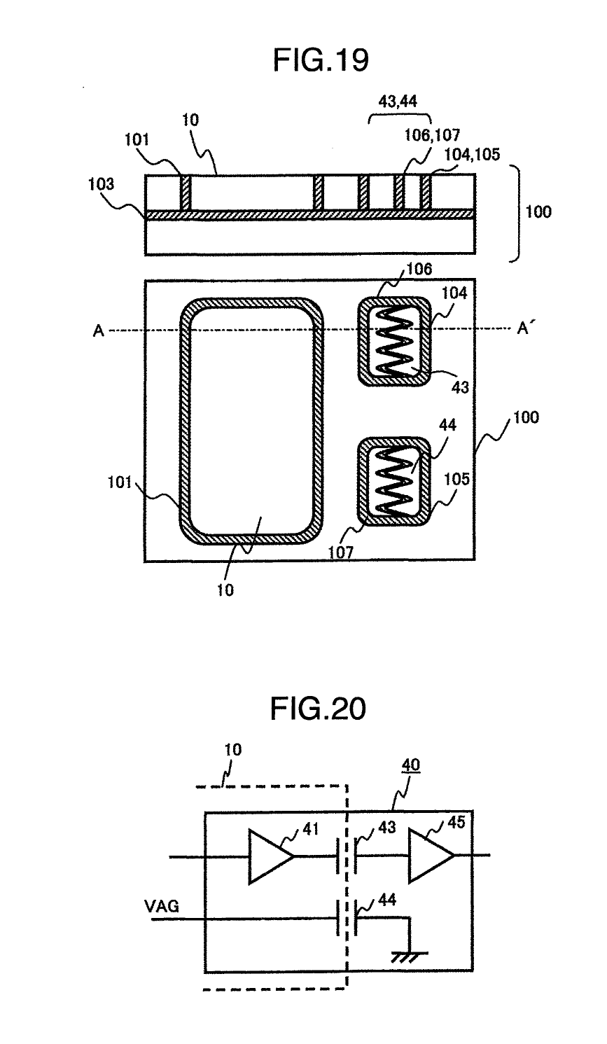

FIGS. 18 and 19 show the isolator 40 according to an embodiment. Incidentally, the technique for realizing the isolator 40 is already disclosed in JP-A-2006-64596. The signal input in the region 10, after driving drivers 41, 42, is differentially input to a receiver 45 located outside the region 10 through capacitors 43, 44 and converted into a signal referenced to GND outside the region 10. The capacitors 43, 44, as shown in FIG. 19, are surrounded by the insulating materials 104, 105, respectively, with the insulating materials 106, 107 interposed therebetween.

### 11th Embodiment

The signal, though transmitted differentially in FIG. 18, can alternatively be transmitted with a single end as shown in FIG. 20. Incidentally, the capacitor 44 may be omitted if a sufficient coupling capacitance can be secured by other paths.

### 12th Embodiment

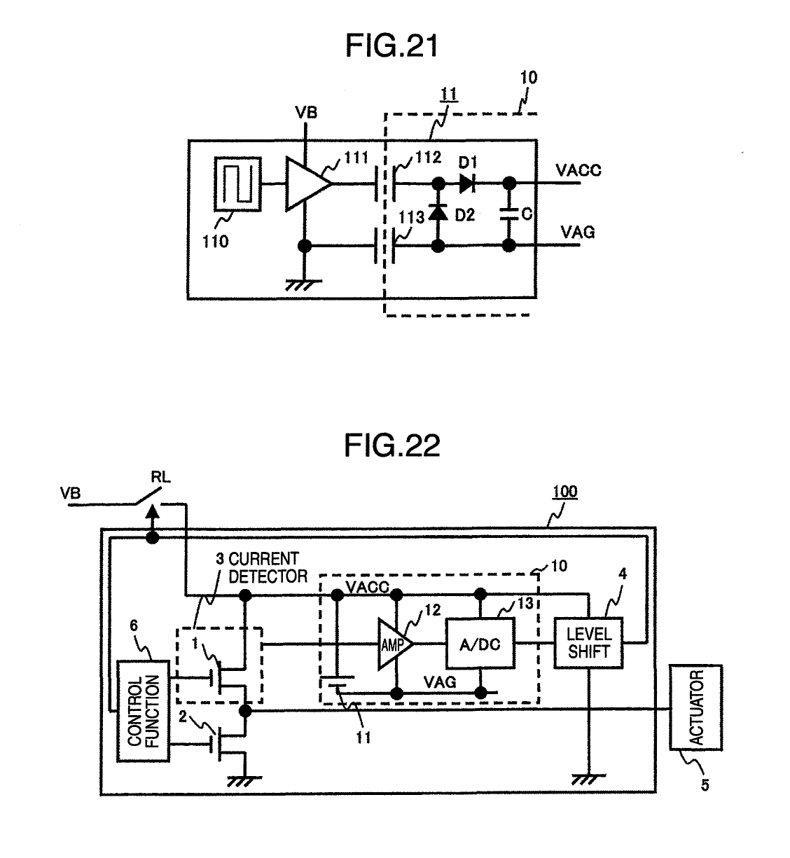

FIG. 21 shows a power supply 11 using a charge pump according to an embodiment. A driver 111 is driven by a clock signal source 110 located outside the region 10. The signal, after being transmitted into the region 10 through a capacitor 112, voltage-doubler rectified into a voltage by diodes D1, D2 thereby to generate VACC having positive potential with respect to VAG. Incidentally, the capacitor 113, though inserted in the return path of the signal, may be omitted if a sufficient coupling capacitance can be secured by other paths. Also, VACC can be stabilized by a regulator after being voltage-doubler rectified by the diodes D1, D2, which is rather desirable for stable operation.

### 13th Embodiment

FIG. 22 shows a control system according to an embodiment of this invention. The semiconductor elements 1, 2 are turned on/off by the control function 6, and the current is supplied to the actuator 5. The current supplied to the actuator 5 is detected by the current detector 3, and after being converted through the amplifier 12 and the A/D converter 13, shifted in level by the level shift unit 4 and input to the control function 6. The control function 6 performs the feedback control operation to achieve a target current of the current flowing in the actuator 5 detected by the current detector 3. According to this embodiment, the semiconductor elements 1, 2, the current detector 3, the amplifier 12, the A/D converter 13 and the level shift unit 4 can be integrated into the same SOI substrate 100, and therefore, the control system can be reduced in size. The control system can be further reduced in size by packaging the control function 6 on the same SOI substrate.

Further, an relay (RL) circuit is desirably controlled to turn on/off the power supply VB with the signal converted by the A/D converter 13 and shifted in level by the level shift unit 4. In this way, by turning off the RL upon detection of an overcurrent, the current can be detected for dual purpose of protection from overcurrent and the detection of the control current, thereby contributing to a reduced cost and size.

Incidentally, the control function 6 can be realized either by the hardware of a fixed logic or a program-controlled microprocessor.

### 14th Embodiment

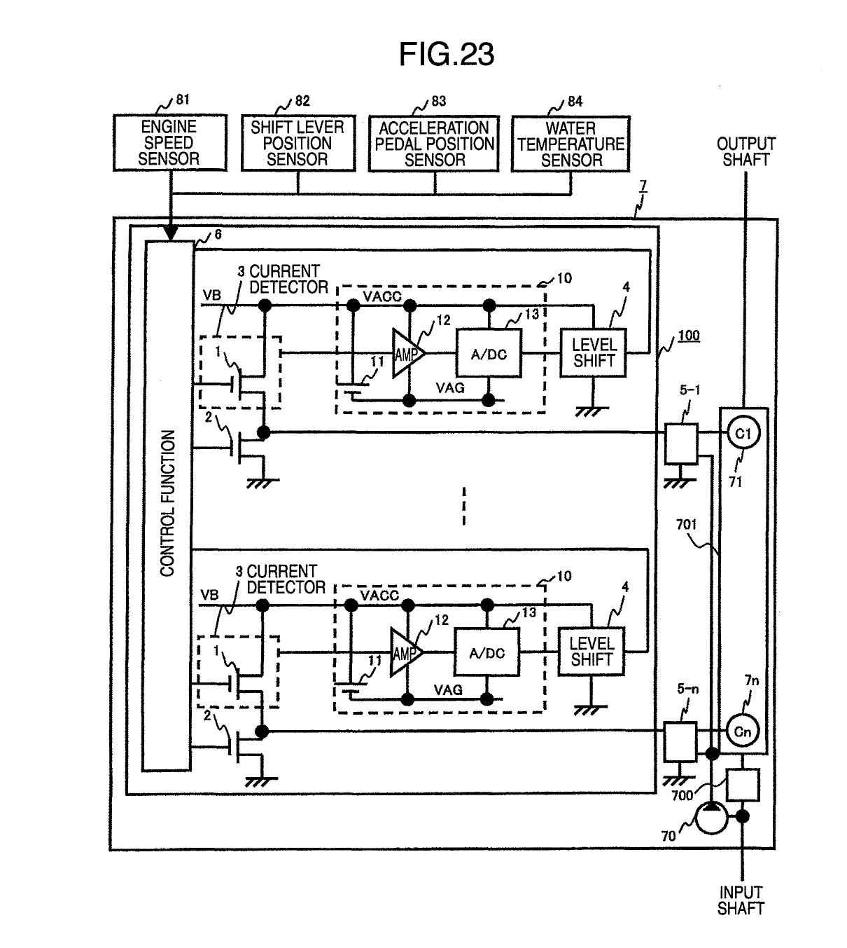

FIG. 23 shows an automatic transmission control system according to an embodiment. The drive output from the engine is applied to the input shaft of an automatic transmission 7, and after being transferred to a speed change gear 701 through a torque converter 700, transferred further to the wheels through a drive shaft and an operation gear.

The control function 6 turns on/off the semiconductor elements 1, 2, and drives linear solenoids 5-1 to 5-n. The linear solenoids 5-1 to 5-n, supplied with the oil pressure from a hydraulic pump 70 driven by the input shaft, controls the oil pressure applied to clutches C1 to Cn. The oil pressure applied to the clutches C1 to Cn from the linear solenoids 5-1 to 5-n can be controlled by the current flowing in the linear solenoids 5-1 to 5-n. The control function 6 is supplied with signals from an engine speed sensor 81, a shift lever position sensor 82, an acceleration pedal position sensor 83 and a water temperature sensor 84. Based on the signals from the engine speed sensor 81, the shift lever position sensor 82, the acceleration pedal position sensor 83 and the water temperature sensor 84 in the operation described above, the control function 6 sets the proper speed change ratio conforming with the running condition by controlling the coupled state of the clutches C1 to Cn. Further, the current flowing in the linear solenoids 5-1 to 5-n which is detected by the current detector 3 is controlled to a target value by feedback. Thus, a smooth operation free of a shift shock is realized.

According to this embodiment, a smooth operation free of shift shock can be realized by controlling the current with a high accuracy. Also, like in the embodiment shown in FIG. 23, the control circuits can be integrated on the same SOI substrate 100, and therefore, the control system can be reduced in size. Also, by controlling the clutches C1 to Cn in finely detailed fashion, not only the shift shock but also the mechanical stress on the automatic transmission 7 can be reduced, thereby making it possible to reduce both the size and weight of the automatic transmission 7.

### 15th Embodiment

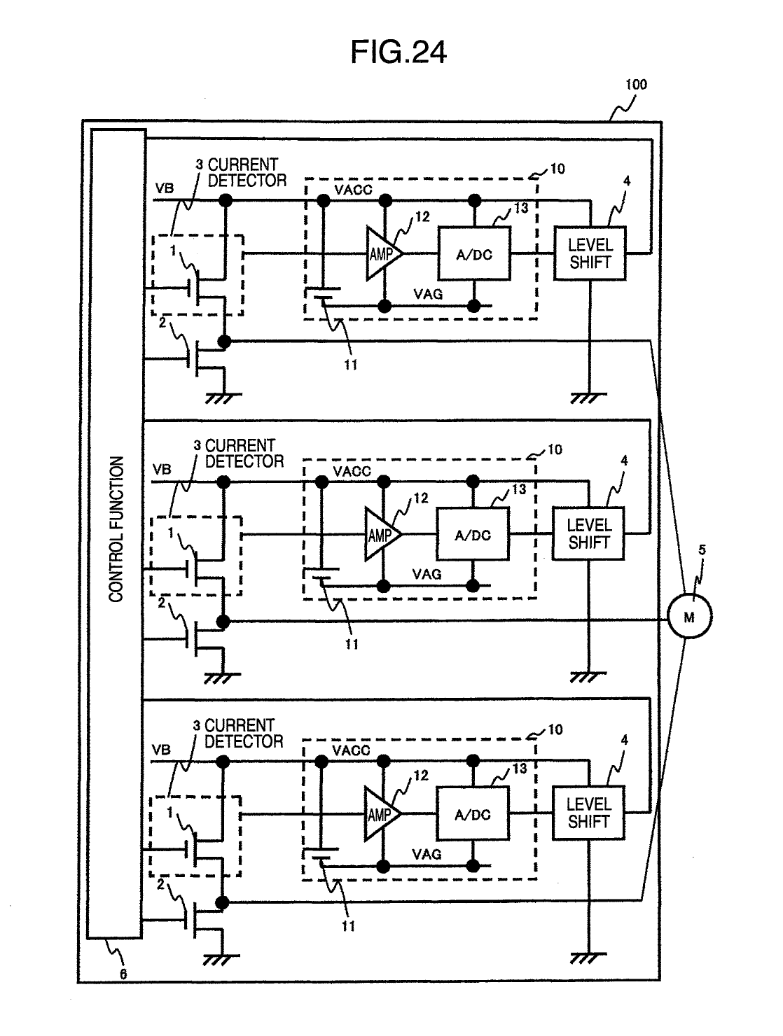

FIG. 24 shows a control system of a DC brushless motor 5 according to an embodiment. The current flowing in each phase of the DC brushless motor 5 which is detected by the current detector 3 is controlled by feedback to a target value by the control function 6. Thus, the motor can be controlled smoothly with higher accuracy. Also, like in the embodiment shown in FIG. 23, the control circuits can be integrated in the same SOI substrate 100, and therefore, the control system is reduced in size. Further, the power steering system and the brake system, which can be driven by the motor 5, are reduced in size. At the same time, a more delicate current control operation is made possible, thereby further improving the riding comfort.

It should be further understood by those skilled in the art that although the foregoing description has been made on embodiments of the invention, the invention is not limited thereto and various changes and modifications may be made without departing from the spirit of the invention and the scope of the appended claims.

1. A current detection apparatus comprising:
a current detector;
a voltage amplifier;
the current detector having an end connected to one of an analog power supply (VACC) and a virtual analog ground potential (VAG) of the voltage amplifier; and
a power supply for supplying a predetermined voltage between the analog power supply (VACC) and the virtual analog ground potential (VAG);
wherein a part of a single semiconductor substrate is isolated from the other part thereof and the voltage amplifier is formed in the isolated part; and
wherein the output voltage of the current detector is amplified by the voltage amplifier.

2. The current detection apparatus according to claim 1,
wherein an analog/digital converter is formed in the part isolated from the other part; and
wherein the analog/digital converter is operated on the analog power supply (VACC) and the virtual analog ground potential (VAG).

3. The current detection apparatus according to claim 1,
wherein a back substrate on the back of the substrate isolated from the other part with the oxide film is connected to an end of the current detector.

4. The current detection apparatus according to claim 1, further comprising an output drive semiconductor element for supplying a current to a load,
wherein the output drive semiconductor element is controlled by the output of the voltage amplifier.

5. The current detection apparatus according to claim 2, further comprising a semiconductor element for supplying a current to a load,
wherein the semiconductor element is controlled by the output of the analog/digital converter.

6. The current detection apparatus according to claim 1,
wherein the current detector is added to a high side output drive semiconductor element.

7. A control system comprising:
the current detection apparatus according to claim 6; and
a relay for switching on/off a power supply;
wherein the relay is turned off by the output of the voltage amplifier.

8. A control system comprising:
the current detection apparatus according to claim 6; and
a relay for switching on/off a power supply;
wherein the relay is turned off by the output of the analog/digital converter.

9. The current detection apparatus according to claim 4,
wherein the current detector, the voltage amplifier, the analog/digital converter and the output drive semiconductor element are formed in a single semiconductor chip.

10. The current detection apparatus according to claim 4,
wherein the output drive semiconductor element drives a linear solenoid, and the clutch and the brake arranged in the speed change gear are operated by the oil pressure output from the linear solenoid.

11. The current detection apparatus according to claim 4,
wherein the output drive semiconductor element drives a motor.

12. The current detection apparatus according to claim 2,
wherein the current detector is added to a high side output drive semiconductor element.

13. A control system comprising:
the current detection apparatus according to claim 12; and
a relay for switching on/off a power supply;
wherein the relay is turned off by the output of the voltage amplifier.

14. A control system comprising:
the current detection apparatus according to claim 12; and
a relay for switching on/off a power supply;
wherein the relay is turned off by the output of the analog/digital converter.

15. The current detection apparatus according to claim 5,
wherein the current detector, the voltage amplifier, the analog/digital converter and the output drive semiconductor element are formed in a single semiconductor chip.

16. The current detection apparatus according to claim 5,
wherein the output drive semiconductor element drives a linear solenoid, and the clutch and the brake arranged in the speed change gear are operated by the oil pressure output from the linear solenoid.

17. The current detection apparatus according to claim 5,
wherein the output drive semiconductor element drives a motor.
